(19) United States
(12) Patent Application Publication
(10) Pub. No.: US 2025/0098432 A1
(43) Pub. Date: Mar. 20, 2025

(54) DISPLAY PANEL AND MANUFACTURING METHOD FOR THE SAME

(71) Applicant: Samsung Display Co., Ltd., Yongin-si (KR)

(72) Inventors: HYUNEOK SHIN, Yongin-si (KR); JOONYONG PARK, Yongin-si (KR); SUKYOUNG YANG, Yongin-si (KR); DONGMIN LEE, Yongin-si (KR)

(73) Assignee: Samsung Display Co., Ltd., Yongin-si (KR)

(21) Appl. No.: 18/767,214

(22) Filed: Jul. 9, 2024

(30) Foreign Application Priority Data
Sep. 15, 2023 (KR) 10-2023-0123375

(51) Int. Cl. H10K 59/122; H10K 59/12; H10K 59/80; H10K 59/88; H10K 71/60; H10K 102/00

(52) U.S. Cl. CPC H10K 59/122; H10K 59/1201; H10K 59/873; H10K 59/88; H10K 71/60; H10K 2102/351

(57) ABSTRACT

A display panel includes a base layer, a pixel defining layer disposed on the base layer and that has a light emitting opening in the pixel defining layer, a barrier wall that has a barrier wall opening in the barrier wall that overlaps the light emitting opening the barrier wall including a first barrier wall layer disposed on the pixel defining layer and a second barrier wall layer disposed on the first barrier wall layer, and a light emitting element disposed in the barrier wall opening and that includes an anode, an intermediate layer, and a cathode that contacts the barrier wall. The first barrier wall layer includes an amorphous alloy.

### CROSS-REFERENCE TO RELATED APPLICATIONS

This application claims priority to and benefits of Korean Patent Application No. 10-2023-0123375 under 35 U.S.C. § 119 filed on Sep. 15, 2023, in the Korean Intellectual Property Office, the entire contents of which are incorporated herein by reference.

### BACKGROUND

### 1. Technical Field

Embodiments described herein relate to a display panel and a display panel manufacturing method, and relate to a display panel with improved display quality.

### 2. Description of the Related Art

Display devices, such as a television, a monitor, a smart phone, a tablet computer, and the like, which provide an image to a user include a display panel that displays an image. Various display panels, such as a liquid crystal display panel, an organic light emitting display panel, an electro wetting display panel, an electrophoretic display panel, and the like, are being developed.

The organic light emitting display panel may include anodes, cathodes, and emission patterns. The emission patterns may be separated for respective emissive regions, and the cathodes may provide a common voltage for the respective emissive regions.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display panel with improved display quality that may include light emitting elements formed without the use of a metal mask, and a method for manufacturing the display panel.

According to an embodiment, a display panel may include a base layer; a pixel defining layer disposed on the base layer and that has a light emitting opening defined in the pixel defining layer; a barrier wall that has a barrier wall opening in the barrier wall that overlaps the light emitting opening and may include a first barrier wall layer disposed on the pixel defining layer and a second barrier wall layer disposed on the first barrier wall layer, and a light emitting element disposed in the barrier wall opening and that may include an anode, an intermediate layer, and a cathode that contacts the barrier wall. The first barrier wall layer may include an amorphous alloy.

The first barrier wall layer may define a first region of the barrier wall opening, and the second barrier wall layer may define a second region of the barrier wall opening. The first region of the barrier wall opening may have a greater width in a first direction than the second region of the barrier wall opening.

The first barrier wall layer may include a first sub-layer disposed on the pixel defining layer and a second sub-layer disposed on the first sub-layer, and the second sub-layer may include the amorphous alloy.

An inner surface of the first sub-layer may be aligned with an inner surface of the second sub-layer.

The cathode may extend along the inner surface of the first sub-layer and the inner surface of the second sub-layer, and an end of the cathode may contact the second sub-layer.

The first sub-layer may have a thickness in a range of about 2000 Å to about 5000 Å.

The second sub-layer may have a thickness in a range of about 2000 Å to about 3000 Å.

The second barrier wall layer may have a thickness in a range of about 1000 Å to about 2500 Å.

The amorphous alloy may include at least one of an amorphous molybdenum alloy and an amorphous tungsten alloy.

The display panel may further include a lower inorganic encapsulation pattern that covers the light emitting element, and a dummy region may be defined between the barrier wall and the lower inorganic encapsulation pattern.

The display panel may further include an organic encapsulation film disposed on the lower inorganic encapsulation pattern, and a portion of the organic encapsulation film may fill the dummy region.

According to an embodiment, a method for manufacturing a display panel may include providing a preliminary display panel including a base layer and a pixel defining layer disposed on the base layer; forming a first preliminary barrier wall layer including an amorphous alloy on the preliminary display panel; forming a second preliminary barrier wall layer on the first preliminary barrier wall layer; forming a second barrier wall layer having a first opening in the second barrier wall layer, by etching the second preliminary barrier wall layer; and forming a first barrier wall layer having a second opening in the first barrier wall layer, by etching the first preliminary barrier wall layer. The first opening in the second barrier wall layer has a smaller width in a first direction than the second opening in the first barrier wall layer.

The forming of the first preliminary barrier wall layer may include forming a first preliminary sub-layer on the pixel defining layer and forming a second preliminary sub-layer on the first preliminary sub-layer.

The forming of the first preliminary sub-layer may include depositing a conductive material to a thickness in a range of about 2000 Å to about 5000 Å.

The forming of the second preliminary sub-layer may include depositing the amorphous alloy to a thickness in a range of about 2000 Å to about 3000 Å.

The second preliminary sub-layer may include at least one of an amorphous molybdenum alloy and an amorphous tungsten alloy.

The forming of the first barrier wall layer having the second opening in the first barrier wall layer by etching the first preliminary barrier wall layer may include forming a second sub-layer by etching the second preliminary sub-layer and forming a first sub-layer by etching the first preliminary sub-layer.

An inner surface of the first sub-layer may be aligned with an inner surface of the second sub-layer.

The forming of the second preliminary barrier wall layer may include depositing a conductive material to a thickness in a range of about 1000 Å to about 2500 Å.

The method may further include forming a light emitting element in the second opening and forming a lower inorganic encapsulation pattern that covers the light emitting element.

### BRIEF DESCRIPTION OF THE DRAWINGS

The above and other objects and features of the disclosure will become apparent by describing in detail embodiments thereof with reference to the accompanying drawings in which:

FIG. 1A is a schematic perspective view of a display device according to an embodiment.

FIG. 1B is an exploded perspective view of the display device according to an embodiment.

FIG. 2 is a sectional view of a display module according to an embodiment.

FIG. 3 is a schematic plan view of a display panel according to an embodiment.

FIG. 4 is a schematic diagram of an equivalent circuit of a pixel according to an embodiment.

FIG. 5 is an enlarged plan view of a portion of a display region of the display panel according to an embodiment.

FIG. 6 is a sectional view of the display panel taken along line I-I′ of FIG. 3 according to an embodiment.

FIG. 7 is a sectional view taken along line II-II′ of FIG. 5.

FIG. 8A is a photo of a section of a second sub-layer according to a comparative example.

FIG. 8B is a photo of a section of a second sub-layer according to an embodiment.

FIGS. 9A to 9K are sectional views illustrating steps of a display panel manufacturing method according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

Identical reference numerals refer to identical components. In the drawings, the thicknesses, proportions, and dimensions of components are exaggerated for effective description.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Terms such as first, second, and the like may be used to describe various components, but the components should not be limited by the terms. The terms may be used only for distinguishing one component from other components. For example, without departing the scope of the disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Hereinafter, embodiments of the disclosure will be described with reference to the accompanying drawings.

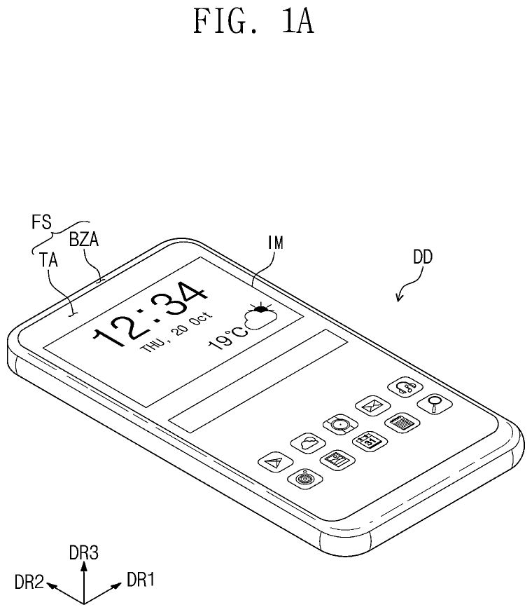

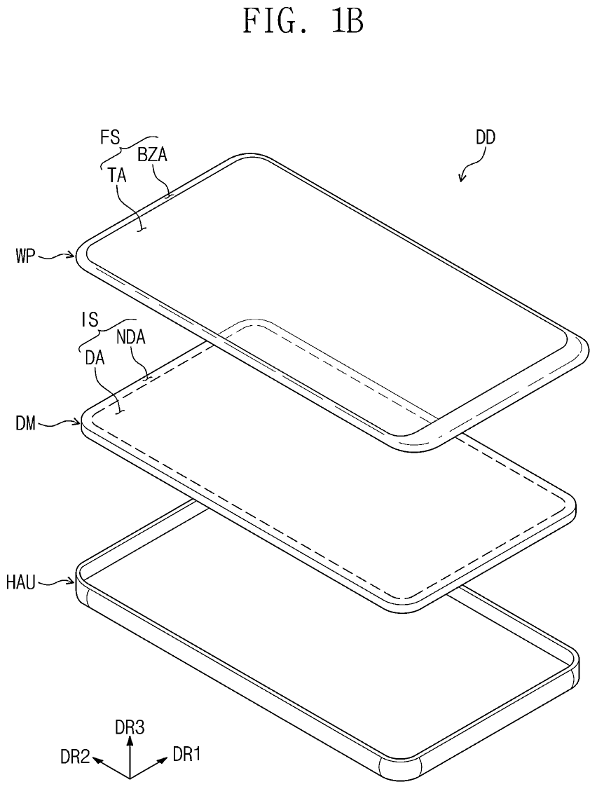

FIG. 1A is a schematic perspective view of a display device DD according to an embodiment, and FIG. 1B is an exploded perspective view of the display device DD according to an embodiment.

In an embodiment, the display device DD may be a large electronic device such as a television, a monitor, or a billboard. By way of example, the display device DD may be a small and medium-sized electronic device such as a personal computer, a notebook computer, a personal digital terminal, a car navigation unit, a game machine, a smart phone, a tablet computer, or a camera. However, this is illustrative, and the display device DD may be employed as other display devices without departing from the spirit and scope of the disclosure. In FIGS. 1A and 1B, the display device DD is a smart phone.

Referring to FIGS. 1A and 1B, the display device DD may display an image IM in a third direction DR3 on a display surface FS parallel to a first direction DR1 and a second direction DR2. The image IM may include a still image as well as a dynamic image. In FIG. 1A, a clock window and icons are illustrated as examples of the image IM. The display surface FS on which the image IM is displayed may correspond to the front surface of the display device DD.

In this embodiment, front surfaces (or, upper surfaces) and rear surfaces (or, lower surfaces) of members are defined based on the direction in which the image IM is displayed. The front surfaces and the rear surfaces may face away from each other in the third direction DR3, and the normal directions of the front surfaces and the rear surfaces may be parallel to the third direction DR3. The directions indicated by the first to third directions DR1, DR2, and DR3 may be relative concepts and may be changed to other directions. As used herein, the expression “when viewed from above the plane” may mean that it is viewed in the third direction DR3.

The display device DD may include a window WP, a display module DM, and a housing HAU. The window WP and the housing HAU may be coupled (or connected) with each other to form the exterior of the display device DD.

The window WP may include an optically clear insulating material. For example, the window WP may include glass or plastic. The front surface of the window WP may define the display surface FS of the display device DD. The display surface FS may include a transmission region TA and a bezel region BZA. The transmission region TA may be an optically clear region. For example, the transmission region TA may be a region having a visible light transmittance of about 90% or more.

The bezel region BZA may be a region having a lower light transmittance than the transmission region TA. The bezel region BZA may define the shape of the transmission region TA. The bezel region BZA may be adjacent to the transmission region TA and may surround the transmission region TA. However, this is illustrative, and the bezel region BZA of the window WP may be omitted. The window WP may include at least one of an anti-fingerprint layer, a hard coating layer, and an anti-reflection layer and is not limited to any one embodiment.

The display module DM may be disposed under or below the window WP. The display module DM may be a component that substantially generates the image IM. The image IM generated by the display module DM is displayed on a display surface IS of the display module DM and visually recognized by a user from the outside through the transmission region TA.

The display module DM may include a display region DA and a non-display region NDA. The display region DA may be a region activated depending on an electrical signal. The non-display region NDA may be adjacent to the display region DA. The non-display region NDA may surround the display region DA. The non-display region NDA may be a region covered by the bezel region BZA and may not be visible from the outside.

The housing HAU may be coupled (or connected) with the window WP. The housing HAU may be coupled (or connected) with the window WP to provide an inner space. The display module DM may be accommodated in the inner space.

The housing HAU may include a material having a relatively high rigidity. For example, the housing HAU may include glass, plastic, or metal, or may include frames and/or plates formed of a combination of the aforementioned materials. The housing HAU may stably protect components of the display device DD accommodated in the inner space from external impact.

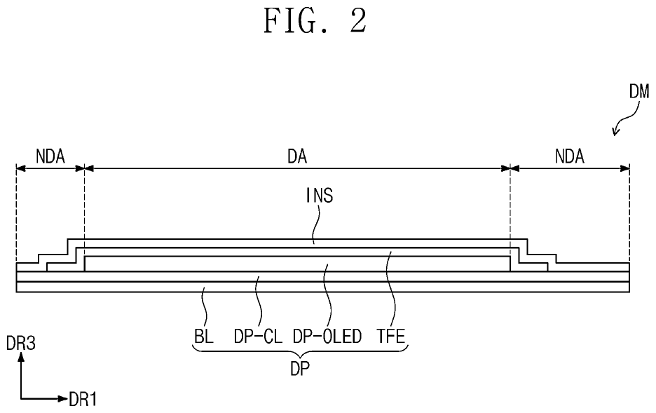

FIG. 2 is a sectional view of the display module DM according to an embodiment.

Referring to FIG. 2, the display module DM may include a display panel DP and an input sensor INS. Although not separately illustrated, the display device DD (refer to FIG. 1A) according to an embodiment may further include a protective member disposed on the lower surface of the display panel DP or an anti-reflection member and/or a window member disposed on the upper surface of the input sensor INS.

The display panel DP may be an emissive display panel. However, this is illustrative, and the disclosure is not particularly limited thereto. For example, the display panel DP may be an organic light emitting display panel or an inorganic light emitting display panel. An emissive layer in the organic light emitting display panel may include an organic luminescent material. An emissive layer in the inorganic light emitting display panel may include quantum dots, quantum rods, or micro LEDs. Hereinafter, the display panel DP is an organic light emitting display panel.

The display panel DP may include a base layer BL, and a circuit element layer DP-CL, a display element layer DP-OLED, and a thin film encapsulation layer TFE that are disposed on the base layer BL. The input sensor INS may be directly disposed on the thin film encapsulation layer TFE. As used herein, the expression “component A is directly disposed on component B” means that an adhesive layer is not disposed between component A and component B.

The base layer BL may include at least one plastic film. The base layer BL may be a flexible substrate and may include a plastic substrate, a glass substrate, a metal substrate, or an organic/inorganic composite substrate. The display region DA and the non-display region NDA described above with reference to FIG. 1B may be identically defined in the base layer BL.

The circuit element layer DP-CL may include at least one insulating layer and a circuit element. The insulating layer may include at least one inorganic layer and at least one organic layer. The circuit element may include signal lines and a pixel drive circuit.

The display element layer DP-OLED may include barrier walls and light emitting elements. Each of the light emitting elements may include an anode, an intermediate layer, and a cathode.

The thin film encapsulation layer TFE may include thin films. Some of the thin films may be disposed to improve optical efficiency, and the other thin films may be disposed to protect the light emitting elements.

The input sensor INS obtains coordinate information of an external input. The input sensor INS may have a multi-layer structure. The input sensor INS may include a single conductive layer or multiple conductive layers. Furthermore, the input sensor INS may include a single insulating layer or multiple insulating layers. The input sensor INS may sense the external input in a capacitive type. However, this is illustrative, and the disclosure is not limited thereto. For example, in an embodiment, the input sensor INS may sense the external input using an electromagnetic induction method or a pressure sensing method. In an embodiment, the input sensor INS may be omitted.

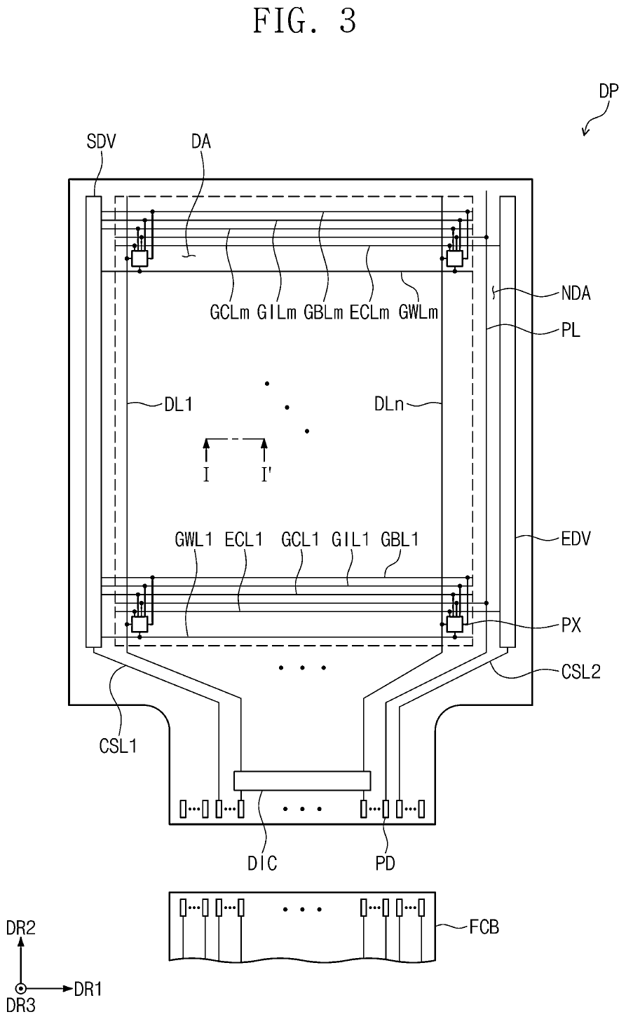

FIG. 3 is a schematic plan view of the display panel DP according to an embodiment.

Referring to FIG. 3, the display region DA and the non-display region NDA around the display region DA may be defined in the display panel DP. The display region DA and the non-display region NDA may be distinguished from each other depending on whether pixels PX are disposed. The pixels PX may be disposed in the display region DA and may not be disposed in the non-display region NDA.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a drive voltage line PL, a scan driver SDV, a data driver, an emission driver EDV, a driver IC DIC, and pads PD. Here, “m” and “n” are natural numbers of 2 or larger. The data driver may be a circuit formed in the driver IC DIC.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driver SDV. The data lines DL1 to DLn may extend in the second direction DR2 and may be electrically connected to the driver IC DIC. The emission control lines ECL1 to ECLm may extend in the first direction DR1 and may be electrically connected to the emission driver EDV.

The drive voltage line PL may include a portion extending in the first direction DR1 and a portion extending in the second portion DR2. The portion extending in the first direction DR1 and the portion extending in the second portion DR2 may be disposed on different layers. The drive voltage line PL may provide a drive voltage to the pixels PL.

The first control line CSL1 may be connected to the scan driver SDV. The second control line CSL2 may be connected to the emission driver EDV.

The driver IC DIC, the drive voltage line PL, the first control line CSL1, and the second control line CSL2 may be electrically connected to the pads PD. A flexible circuit film FCB may be electrically connected to the pads PD through an anisotropic conductive adhesive layer. The pads PD may be pads for connecting the flexible circuit film FCB to the display panel DP. The pads PD may be connected to the corresponding pixels PX through the drive voltage line PL, the first control line CSL1, and the second control line CSL2.

The pads PD may further include input pads. The input pads may be pads for connecting the flexible circuit film FCB to the input sensor INS (refer to FIG. 2). However, without being limited thereto, the input pads may be disposed in the input sensor INS and may be connected with the pads PD and a separate circuit board. By way of example, the input sensor INS may be omitted, and the input pads may not be further included.

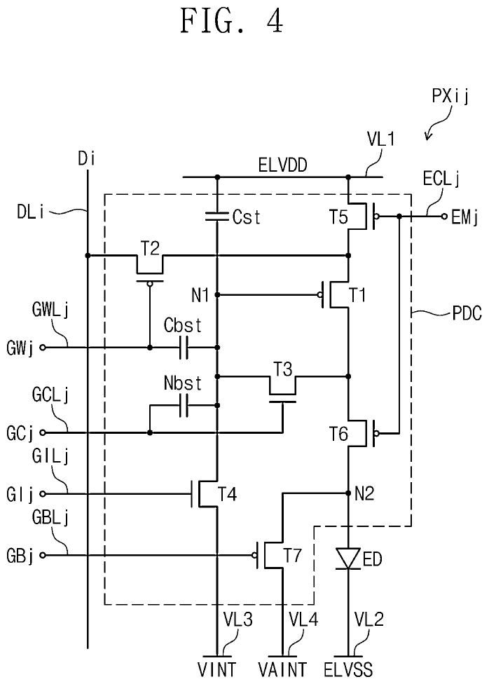

FIG. 4 is an equivalent circuit diagram of a pixel PXij according to an embodiment.

In FIG. 4, an equivalent circuit diagram of one pixel PXij among the pixels PX (refer to FIG. 3) is illustrated as an example. Since the pixels PX have the same circuit structure, description of the circuit structure for the pixel PXij may be applied to the remaining pixels PX, and detailed description of the remaining pixels PX will be omitted.

Referring to FIGS. 3 and 4, the pixel PXij is connected to the i-th data line DLi among the data lines DL1 to DLn, the j-th initialization scan line GILj among the initialization scan lines GIL1 to GILm, the j-th compensation scan line GCLj among the compensation scan lines GCL1 to GCLm, the j-th write scan line GWLj among the write scan lines GWL1 to GWLm, the j-th black scan line GBLj among the black scan lines GBL1 to GBLm, the j-th emission control line ECLj among the emission control lines ECL1 to ECLm, first and second drive voltage lines VL1 and VL2, and first and second initialization voltage lines VL3 and VL4. Here, “i” is an integer of 1 to n, and “j” is an integer of 1 to m.

The pixel PXij may include a light emitting element ED and a pixel circuit PDC. The light emitting element ED may be a light emitting diode. In an embodiment, the light emitting element ED may be an organic light emitting diode including an organic light emitting layer, but is not particularly limited thereto. The pixel circuit PDC may control the amount of current flowing through the light emitting element ED in response to a data signal Di. The light emitting element ED may emit light having a given luminance in response to the amount of current provided from the pixel circuit PDC.

The pixel circuit PDC may include first to seventh transistors T1, T2, T3, T4, T5, T6, and T7 and first to third capacitors Cst, Cbst, and Nbst. The configuration of the pixel circuit PDC according to the disclosure is not limited to the embodiment illustrated in FIG. 4. The pixel circuit PDC illustrated in FIG. 4 is illustrative, and various changes and modifications may be made to the configuration of the pixel circuit PDC.

At least one of the first to seventh transistors T1, T2, T3, T4, T5, T6, and T7 may be a transistor having a low-temperature polycrystalline silicon (LTPS) semiconductor layer. At least one of the first to seventh transistors T1, T2, T3, T4, T5, T6, and T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

By way of example, the first transistor T1 directly affecting the brightness of the light emitting element ED may include a semiconductor layer formed of polycrystalline silicon having high reliability, and thus the display device having a high resolution may be implemented. An oxide semiconductor has high carrier mobility and low leakage current, and thus a voltage drop is not great even though operating time is long. For example, the color of an image is not greatly changed depending on a voltage drop even during a low-frequency operation, and thus the low-frequency operation is possible. Since the oxide semiconductor has an advantage of low leakage current as described above, at least one of the third transistor T3, which is connected with a gate electrode of the first transistor T1, and the fourth transistor T4 may be employed as an oxide semiconductor to reduce power consumption while preventing leakage current that is likely to flow to the gate electrode.

Some of the first to seventh transistors T1, T2, T3, T4, T5, T6, and T7 may be P-type transistors, and the others may be N-type transistors. For example, the first, second, fifth, sixth, and seventh transistors T1, T2, T5, T6, and T7 may be P-type transistors, and the third and fourth transistors T3 and T4 may be N-type transistors.

The configuration of the pixel circuit PDC according to the disclosure is not limited to the embodiment illustrated in FIG. 4. The pixel circuit PDC illustrated in FIG. 4 is illustrative, and various changes and modifications may be made to the configuration of the pixel circuit PDC. For example, the first to seventh transistors T1, T2, T3, T4, T5, T6, and T7 may all be P-type transistors or N-type transistors. By way of example, the first, second, fifth, and sixth transistors T1, T2, T5, and T6 may be P-type transistors, and the third, fourth, and seventh transistors T3, T4, and T7 may be N-type transistors.

The j-th initialization scan line GILj, the j-th compensation scan line GCLj, the j-th write scan line GWLj, the j-th black scan line GBLj, and the j-th emission control line ECLj may transmit the j-th initialization scan signal GIj, the j-th compensation scan signal GCj, the j-th write scan signal GWj, the j-th black scan signal GBj, and the j-th emission control signal EMj to the pixel PXji, respectively. The i-th data line DLi transfers the i-th data signal Di to the pixel PXij. The i-th data signal Di may have a voltage level corresponding to an image signal that is input to the display device DD (refer to FIG. 1A).

The first and second drive voltage lines VL1 and VL2 may transfer a first drive voltage ELVDD and a second drive voltage ELVSS to the pixel PXij, respectively. The first and second initialization voltage lines VL3 and VL4 may transfer a first initialization voltage VINT and a second initialization voltage VAINT to the pixel PXij, respectively.

The first transistor T1 is connected between the first drive voltage line VL1, which receives the first drive voltage ELVDD, and the light emitting element ED. The first transistor T1 may include a first electrode connected with the first drive voltage line VL1 via the fifth transistor T5, a second electrode connected with a pixel electrode (or, referred to as an anode) of the light emitting element ED via the sixth transistor T6, and a third electrode (for example, a gate electrode) connected with one end or an end of the first capacitor Cst (for example, a first node N1). The first transistor T1 may receive the i-th data signal Di that the i-th data line DLi transfers depending on a switching operation of the second transistor T2 and may supply a drive current to the light emitting element ED. A second node N2 may also be included.

The second transistor T2 is connected between the i-th data line DLi and the first electrode of the first transistor T1. The second transistor T2 may include a first electrode connected with the i-th data line DLi, a second electrode connected with the first electrode of the first transistor T1, and a third electrode (for example, a gate electrode) connected with the j-th write scan line GWLj. The second transistor T2 may be turned on depending on the j-th write scan signal GWj transferred through the j-th write scan line GWLj and may transfer, to the first electrode of the first transistor T1, the i-th data signal Di transferred from the i-th data line DLi. One end or an end of the second capacitor Cbst may be connected to the third electrode of the second transistor T2, and an opposite end of the second capacitor Cbst may be connected to the first node N1.

The third transistor T3 is connected between the second electrode of the first transistor T1 and the first node N1. The third transistor T3 may include a first electrode connected with the third electrode of the first transistor T1, a second electrode connected with the second electrode of the first transistor T1, and a third electrode (for example, a gate electrode) connected with the j-th compensation scan line GCLj. The third transistor T3 may be turned on depending on the j-th compensation scan signal GCj transferred through the j-th compensation scan line GCLj and may diode-connect the first transistor T1 by connecting the third electrode of the first transistor T1 and the second electrode of the first transistor T1. One end or an end of the third capacitor Nbst may be connected to the third electrode of the third transistor T3, and an opposite end of the third capacitor Nbst may be connected to the first node N1.

The fourth transistor T4 is connected between the first initialization voltage line VL3 through which the first initialization voltage VINT is applied and the first node N1. The fourth transistor T4 may include a first electrode connected with the first initialization voltage line VL3 through which the first initialization voltage VINT is transferred, a second electrode connected with the first node N1, and a third electrode (for example, a gate electrode) connected with the j-th initialization scan line GILj. The fourth transistor T4 is turned on depending on the j-th initialization scan signal GIj transferred through the j-th initialization scan line GILj. The turned-on fourth transistor T4 initializes the potential of the third electrode of the first transistor T1 (for example, the potential of the first node N1) by transferring the first initialization voltage VINT to the first node N1.

The fifth transistor T5 may include a first electrode connected with the first drive voltage line VL1, a second electrode connected with the first electrode of the first transistor T1, and a third electrode (for example, a gate electrode) connected to the j-th emission control line ECLj. The sixth transistor T6 may include a first electrode connected with the second electrode of the first transistor T1, a second electrode connected to the pixel electrode of the light emitting element ED, and a third electrode (for example, a gate electrode) connected to the j-th emission control line ECLj.

The fifth and sixth transistors T5 and T6 are simultaneously turned on depending on the j-th emission control signal EMj transferred through the j-th emission control line ECLj. The first drive voltage ELVDD applied through the turned-on fifth transistor T5 may be compensated for through the diode-connected first transistor T1 and thereafter may be transferred to the light emitting element ED through the sixth transistor T6.

The seventh transistor T7 may include a first electrode connected to the second initialization voltage line VL4 through which the second initialization voltage VAINT is transferred, a second electrode connected with the second electrode of the sixth transistor T6, and a third electrode (for example, a gate electrode) connected with the j-th black scan line GBLj. The second initialization voltage VAINT may have a voltage level lower than or equal to the voltage level of the first initialization voltage VINT.

The one end or an end of the first capacitor Cst is connected with the third electrode of the first transistor T1, and an opposite end of the first capacitor Cst is connected with the first drive voltage line VL1. A cathode of the light emitting element ED may be connected with the second drive voltage line VL2 that transfers the second drive voltage ELVSS. The second drive voltage ELVSS may have a lower voltage level than the first drive voltage ELVDD.

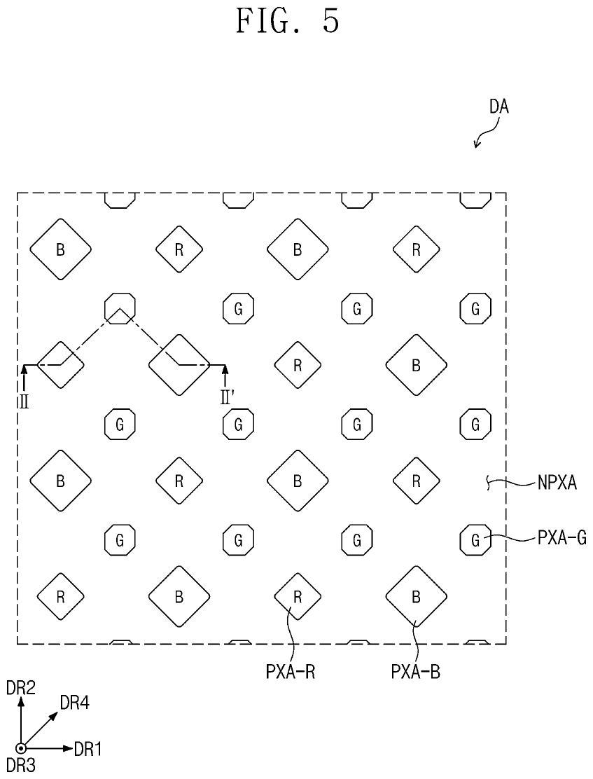

FIG. 5 is an enlarged plan view of a portion of the display region DA (refer to FIG. 2) of the display panel DP (refer to FIG. 2) according to an embodiment. FIG. 5 is a schematic plan view of the display module DM as viewed from above the display surface IS (refer to FIG. 1B) of the display module DM (refer to FIG. 1B) and illustrates an arrangement of emissive regions PXA-R, PXA-G, and PXA-B.

Referring to FIG. 5, the display region DA may include the first to third emissive regions PXA-R, PXA-G, and PXA-B and a peripheral region NPXA surrounding the first to third emissive regions PXA-R, PXA-G, and PXA-B. The first to third emissive regions PXA-R, PXA-G, and PXA-B may correspond to regions through which light provided from light emitting elements is emitted. The first to third emissive regions PXA-R, PXA-G, and PXA-B may be distinguished from one another depending on the colors of light emitted toward the outside of the display module DM (refer to FIG. 2).

The first to third emissive regions PXA-R, PXA-G, and PXA-B may provide first color light, second color light, and third color light that have different colors, respectively. For example, the first color light may be red light, the second color light may be green light, and the third color light may be blue light. However, examples of the first color light, the second color light, and the third color light are not necessarily limited thereto.

The first to third emissive regions PXA-R, PXA-G, and PXA-B may be defined as regions where upper surfaces of anodes are exposed by light emitting openings that will be described below. The peripheral region NPXA may set the boundaries between the first to third emissive regions PXA-R, PXA-G, and PXA-B and may prevent color mixing between the first to third emissive regions PXA-R, PXA-G, and PXA-B.

First emissive regions PXA-R, second emissive regions PXA-G, and third emissive regions PXA-B may be provided. The first emissive regions PXA-R, the second emissive regions PXA-G, and the third emissive regions PXA-B may have a predetermined arrangement in the display region DA and may be repeatedly disposed. For example, the first and third emissive regions PXA-R and PXA-B may be alternately arranged (or disposed) in the first direction DR1 to form a “first group”. The second emissive regions PXA-G may be arranged in the first direction DR1 to form a “second group”. The “first group” and the “second group” may be provided in plural numbers, and the “first groups” and the “second groups” may be alternately arranged in the second direction DR2.

One second emissive region PXA-G may be spaced apart from one first emissive region PXA-R or one third emissive region PXA-B in a fourth direction DR4. The fourth direction DR4 may be defined as a direction between the first and second directions DR1 and DR2.

FIG. 5 illustrates an arrangement of the first to third emissive regions PXA-R, PXA-G, and PXA-B, and without being limited thereto, the first to third emissive regions PXA-R, PXA-G, and PXA-B may be arranged in various forms. In an embodiment, as illustrated in FIG. 5, the first to third emissive regions PXA-R, PXA-G, and PXA-B may have a PENTILE™ arrangement form. By way of example, the first to third emissive regions PXA-R, PXA-G, and PXA-B may have a stripe arrangement form or a Diamond Pixel™ arrangement form.

The first to third emissive regions PXA-R, PXA-G, and PXA-B may have various shapes when viewed from above the plane. For example, the first to third emissive regions PXA-R, PXA-G, and PXA-B may have a polygonal, circular, or oval shape. FIG. 5 illustrates the first and third emissive regions PXA-R and PXA-B having a quadrangular shape (or, a rhombic shape) when viewed from above the plane and the second emissive regions PXA-G having an octagonal shape when viewed from above the plane.

When viewed from above the plane, the first to third emissive regions PXA-R, PXA-G, and PXA-B may have the same shape, or at least some of the first to third emissive regions PXA-R, PXA-G, and PXA-B may have different shapes. FIG. 5 illustrates the first and third emissive regions PXA-R and PXA-B having the same shape when viewed from above the plane and the second emissive region PXA-G having a shape different from those of the first and third emissive regions PXA-R and PXA-B when viewed from above the plane.

At least some of the first to third emissive regions PXA-R, PXA-G, and PXA-B may have different areas when viewed from above the plane. In an embodiment, the area of the first emissive region PXA-R emitting red light may be greater than the area of the second emissive region PXA-G emitting green light and may be smaller than the area of the third emissive region PXA-B emitting blue light. However, the relative size relationship between the first to third emissive regions PXA-R, PXA-G, and PXA-B depending on the colors of emitted light is not limited thereto and may vary depending on the design of the display module DM (refer to FIG. 2). Furthermore, without being limited thereto, the first to third emissive regions PXA-R, PXA-G, and PXA-B may have the same area when viewed from above the plane.

The shapes, areas, and arrangement of the first to third emissive regions PXA-R, PXA-G, and PXA-B of the display module DM (refer to FIG. 2) of the disclosure may be designed in various ways depending on the colors of emitted light or the size and configuration of the display module DM (refer to FIG. 2) and are not limited to the embodiment illustrated in FIG. 6.

FIG. 6 is a sectional view of the display panel taken along line I-I′ of FIG. 3 according to an embodiment. In describing FIG. 6, the description will be made with reference to FIG. 2, and descriptions of the same reference numerals will be omitted.

FIG. 6 is a sectional view of the display panel taken along line I-I′ of FIG. 3 of one emissive region PXA in the display region DA (refer to FIG. 5), and the emissive region PXA of FIG. 6 may correspond to one of the first to third emissive regions PXA-R, PXA-G, and PXA-B of FIG. 5. Referring to FIG. 6, the display panel DP may include the base layer BL, the circuit element layer DP-CL, the display element layer DP-OLED, and the thin film encapsulation layer TFE.

The display panel DP may include insulating layers, a semiconductor pattern, a conductive pattern, and a signal line. An insulating layer, a semiconductor layer, and a conductive layer are formed by coating, deposition, or the like within the spirit and the scope of the disclosure. Thereafter, the insulating layer, the semiconductor layer, and the conductive layer may be selectively subjected to patterning by photolithography and etching. The semiconductor pattern, the conductive pattern, and the signal line included in the circuit element layer DP-CL and the display element layer DP-OLED may be formed by the above-described method.

The circuit element layer DP-CL may be disposed on the base layer BL. The circuit element layer DP-CL may include a buffer layer BFL, a transistor TR1, a signal transmission region SCL, first to fifth insulating layers 10, 20, 30, 40, and 50, an electrode EE, and connecting electrodes CNE1 and CNE2.

The buffer layer BFL may be disposed on the base layer BL. The buffer layer BFL may improve a coupling force between the base layer BL and a semiconductor pattern. The buffer layer BFL may include silicon oxide layers and silicon nitride layers. The silicon oxide layers and the silicon nitride layers may be alternately stacked one above another.

The semiconductor pattern may be disposed on the buffer layer BFL. The semiconductor pattern may include poly-silicon. However, without being limited thereto, the semiconductor pattern may include amorphous silicon or metal oxide. In FIG. 6, a portion of the semiconductor pattern is illustrated as an example, and the semiconductor pattern may be additionally disposed in the emissive regions PXA-R, PXA-G, PXA-B (refer to FIG. 5). The semiconductor pattern may be arranged across the emissive regions PXA-R, PXA-G, PXA-B according to a selectable rule. The semiconductor pattern may have different electrical properties depending on whether the semiconductor pattern is doped or not. The semiconductor pattern may include a first region having a high doping concentration and a second region having a low doping concentration. The first region may be doped with an N-type dopant or a P-type dopant. A P-type transistor may include a first region doped with a P-type dopant.

The first region has a higher conductivity than the second region and substantially serves as an electrode or a signal line. The second region may substantially correspond to an active (or, channel) region of the transistor. In other words, one portion of the semiconductor pattern may be the active region of the transistor, another portion may be a source or drain of the transistor, and another portion may be a conductive region.

The source S, the active region A, and the drain D of the transistor TR1 may be formed from the semiconductor pattern. A portion of the signal transmission region SCL formed from the semiconductor pattern is illustrated in FIG. 6. Although not separately illustrated, the signal transmission region SCL may be connected to the drain D of the transistor TR1 when viewed from above the plane.

The first to fifth insulating layers 10, 20, 30, 40, and 50 may be disposed on the buffer layer BFL. The first to fifth insulating layers 10, 20, 30, 40, and 50 may be inorganic layers or organic layers.

The first insulating layer 10 may be disposed on the buffer layer BFL. The first insulating layer 10 may cover the source S, the active region A, and the drain D of the transistor TR1 and the signal transmission region SCL that are disposed on the buffer layer BFL. A gate G of the transistor TR1 may be disposed on the first insulating layer 10. The second insulating layer 20 may be disposed on the first insulating layer 10 and may cover the gate G. The electrode EE may be disposed on the second insulating layer 20. The third insulating layer 30 may be disposed on the second insulating layer 20 and may cover the electrode EE.

The first connecting electrode CNE1 may be disposed on the third insulating layer 30. The first connecting electrode CNE1 may be connected to the signal transmission region SCL through a contact hole CNT-1 penetrating the first to third insulating layers 10, 20, and 30. The fourth insulating layer 40 may be disposed on the third insulating layer 30 and may cover the first connecting electrode CNE1. The fourth insulating layer 40 may be an organic layer.

The second connecting electrode CNE2 may be disposed on the fourth insulating layer 40. The second connecting electrode CNE2 may be connected to the first connecting electrode CNE1 through a contact hole CNT-2 penetrating the fourth insulating layer 40. The fifth insulating layer 50 may be disposed on the fourth insulating layer 40 and may cover the second connecting electrode CNE2. The fifth insulating layer 50 may be an organic layer.

The display element layer DP-OLED may be disposed on the circuit element layer DP-CL. The display element layer DP-OLED may include a light emitting element ED, a sacrificial pattern SP, a pixel defining layer PDL, and a barrier wall PW.

The light emitting element ED may include an anode AE (or, a first electrode), an emission pattern EP, and a cathode CE (or, a second electrode).

The anode AE may be disposed on the fifth insulating layer 50 of the circuit element layer DP-CL. The anode AE may be a transmissive electrode, a transflective electrode, or a reflective electrode. The anode AE may be connected to the second connecting electrode CNE2 by a connection contact hole CNT-3 defined to penetrate the fifth insulating layer 50. Accordingly, the anode AE may be electrically connected to the signal transmission region SCL through the first and second connecting electrodes CNE1 and CNE2 and may be electrically connected to a corresponding circuit element. The anode AE may include a single-layer structure or a multi-layer structure. The anode AE may include layers including ITO and Ag. For example, the anode AE may include a layer including ITO (hereinafter, referred to as the lower IOT layer), a layer disposed on the lower ITO layer and including Ag (hereinafter, referred to as the Ag layer), and a layer disposed on the Ag layer and including ITO (hereinafter, referred to as the upper ITO layer).

The sacrificial pattern SP may be disposed between the anode AE and the pixel defining layer PDL. A sacrificial opening OP-S that exposes a portion of the upper surface of the anode AE may be defined in the sacrificial pattern SP. The sacrificial opening OP-S may overlap a light emitting opening OP-E that will be described below.

The pixel defining layer PDL may be disposed on the fifth insulating layer 50 of the circuit element layer DP-CL. The pixel defining layer PDL may have the light emitting opening OP-E defined therein. The light emitting opening OP-E may correspond to the anode AE, and the pixel defining layer PDL may expose at least a portion of the anode AE through the light emitting opening OP-E.

The light emitting opening OP-E may correspond to the sacrificial opening OP-S of the sacrificial pattern SP. According to this embodiment, the upper surface of the anode AE may be spaced apart from the pixel defining layer PDL on the section with the sacrificial pattern SP therebetween. Accordingly, damage to the anode AE in a process of forming the light emitting opening OP-E may be prevented.

The area of the light emitting opening OP-E may be smaller than the area of the sacrificial opening OP-S when viewed from above the plane. For example, the inner surface of the pixel defining layer PDL that defines the light emitting opening OP-E may be closer to the center of the anode AE than the inner surface of the sacrificial pattern SP that defines the sacrificial opening OP-S. However, without being limited thereto, the inner surface of the sacrificial pattern SP that defines the sacrificial opening OP-S may be substantially aligned with the inner surface of the pixel defining layer PDL that defines the light emitting opening OP-E. At this time, the emissive region PXA may be regarded as a region of the anode AE exposed from the corresponding sacrificial opening OP-S.

The pixel defining layer PDL may include an inorganic insulating material. For example, the pixel defining layer PDL may include silicon nitride SiNₓ. The pixel defining layer PDL may be disposed between the anode AE and the barrier wall PW and may block electrical connection between the anode AE and the barrier wall PW.

The emission pattern EP may be disposed on the anode AE. The emission pattern EP may include an emissive layer including a luminescent material. The emission pattern EP may further include a hole injection layer (HIL) and a hole transport layer (HTL) that are disposed between the anode AE and the emissive layer and may further include an electron transport layer (ETL) and an electron injection layer (EIL) that are disposed on the emissive layer. The emission pattern EP may be referred to as an “organic layer” or an “intermediate layer”.

The emission pattern EP may be subjected to patterning by a tip portion defined in the barrier wall PW. The emission pattern EP may be disposed in the sacrificial opening OP-S, the light emitting opening OP-E, and a barrier wall opening OP-P. The emission pattern EP may cover a portion of the upper surface of the pixel defining layer PDL exposed from the barrier wall opening OP-P.

The cathode CE may be disposed on the emission pattern EP. The cathode CE may be subjected to patterning by the tip portion defined in the barrier wall PW. At least a portion of the cathode CE may be disposed in the barrier wall opening OP-P. The cathode CE may make contact with a first inner surface S-LS1 and S-LS2 of a first barrier wall layer L1. For example, the cathode CE may extend along an inner surface S-LS1 of a first sub-layer LS1 and an inner surface S-LS2 of a second sub-layer LS2 that will be described below, and ends of the cathode CE may make contact with the second sub-layer LS2.

The cathode CE may have conductivity. As long as the cathode CE is capable of having conductivity, the cathode CE may be formed of various materials such as metal, transparent conductive oxide (TCO), or a conductive polymer material. For example, the cathode CE may include silver (Ag), magnesium (Mg), lead (Pb), copper (Cu), or a compound thereof.

In an embodiment, the display element layer DP-OLED may further include a capping pattern. The capping pattern may be disposed in the barrier wall opening OP-P and may be disposed on the cathode CE. The capping pattern may be subjected to patterning by the tip portion formed in the barrier wall PW.

The barrier wall PW may be disposed on the pixel defining layer PDL. The barrier wall PW may have the barrier wall opening OP-P defined therein. The barrier wall opening OP-P may correspond to the light emitting opening OP-E and may expose at least a portion of the anode AE.

The barrier wall PW may have an undercut shape on the section. The barrier wall PW may include multiple layers sequentially stacked one above another, and at least one layer among the multiple layers may be recessed relative to the other layers. Accordingly, the barrier wall PW may include the tip portion.

The barrier wall PW may include the first barrier wall layer L1 and a second barrier wall layer L2. The first barrier wall layer L1 may be disposed on the pixel defining layer PDL, and the second barrier wall layer L2 may be disposed on the first barrier wall layer L1. As illustrated in FIG. 6, the thickness of the first barrier wall layer L1 may be greater than the thickness of the second barrier wall layer L2. However, the disclosure is not limited thereto.

In case that compared to the second barrier wall layer L2, the first barrier wall layer L1 may be relatively recessed with respect to the emissive region PXA. The first barrier wall layer L1 may be undercut with respect to the second barrier wall layer L2. The portion of the second barrier wall layer L2 that protrudes from the first barrier wall layer L1 toward the emissive region PXA may be defined as the tip portion within the barrier wall PW.

The barrier wall opening OP-P defined in the barrier wall PW may include a first region A1 and a second region A2. The width of the first region A1 may be different from the width of the second region A2. The width of the first region A1 in the first direction DR1 may be greater than the width of the second region A2 in the first direction DR1. In this case, the second region A2 of the barrier wall opening OP-P may be a region that defines the tip portion. For example, due to the protruding tip portion, the second region A2 may have a narrower width than the first region A1.

The first barrier wall layer L1 may include the first inner surface S-LS1 and S-LS2 that defines the first region A1 of the barrier wall opening OP-P, and the second barrier wall layer L2 may include a second inner surface S-L2 that defines the second region A2 of the barrier wall opening OP-P. On the section, the second inner surface S-L2 of the second barrier wall layer L2 may be closer to the center of the anode AE than the first inner surface S-LS1 and S-LS2 of the first barrier wall layer L1. The first inner surface S-LS1 and S-LS2 may be recessed in a direction away from the center of the anode AE with respect to the second inner surface S-L2. Accordingly, the second barrier wall layer L2 protruding toward the emissive region PXA may include the tip portion.

The first barrier wall layer L1 may include the first sub-layer LS1 and the second sub-layer LS2. The first sub-layer LS1 may be disposed on the pixel defining layer PDL, and the second sub-layer LS2 may be disposed on the first sub-layer LS1. The first inner surface S-LS1 and S-LS2 of the first barrier wall layer L1 may include the inner surface S-LS1 of the first sub-layer LS1 and the inner surface S-LS2 of the second sub-layer LS2. The inner surface S-LS1 of the first sub-layer LS1 and the inner surface S-LS2 of the second sub-layer LS2 may be aligned with each other. The thickness T-LS1 of the first sub-layer LS1 may range from about 2000 Å to about 5000 Å, and the thickness T-LS2 of the second sub-layer LS2 may range from about 2000 Å to about 3000 Å. The thickness T-L2 of the second barrier wall layer L2 may range from about 1000 Å to about 2500 Å.

Each of the first barrier wall layer L1 and the second barrier wall layer L2 may include a conductive material. For example, the conductive material may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

By way of example, the first barrier wall layer L1 may include an amorphous alloy. In detail, the second sub-layer LS2 of the first barrier wall layer L1 may include the amorphous alloy. The amorphous alloy may include at least one of an amorphous molybdenum alloy and an amorphous tungsten alloy. For example, the second sub-layer LS2 may include an alloy in which nickel (Ni) and titanium (Ti) are combined with molybdenum (Mo) at a ratio of about 20% to about 30% or an alloy in which nickel (Ni) and tantalum (Ta) are combined with molybdenum (Mo) at a ratio of about 20% to about 30%. However, this is illustrative, and metals of the second sub-layer LS2 and the ratio thereof are not limited to the above examples.

Although FIG. 6 illustrates an example that the first inner surface S-LS1 and S-LS2 and the second inner surface S-L2 are perpendicular to the upper surface of the pixel defining layer PDL, the disclosure is not limited thereto. For example, the barrier wall PW may have a tapered shape or an inverted tapered shape.

The barrier wall PW may receive the second drive voltage ELVSS (refer to FIG. 4). Accordingly, the cathode CE may be electrically connected to the barrier wall PW and may receive the second drive voltage ELVSS (refer to FIG. 4).

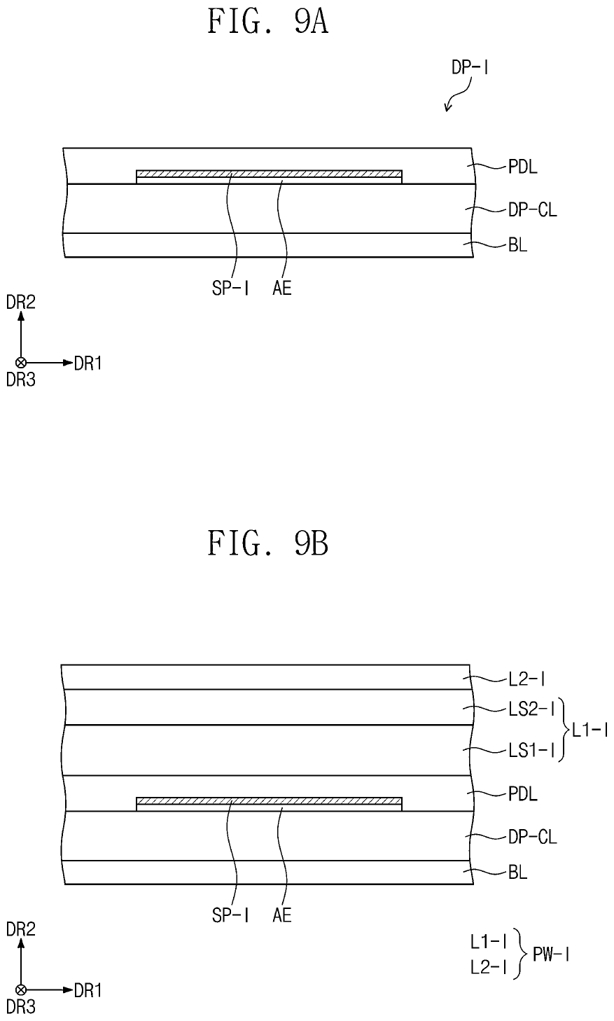

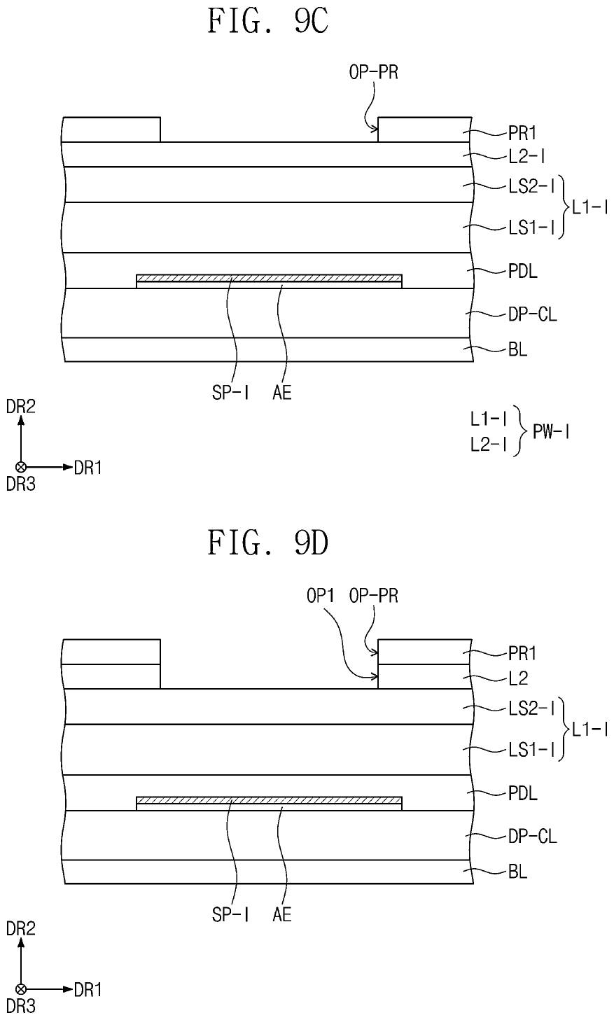

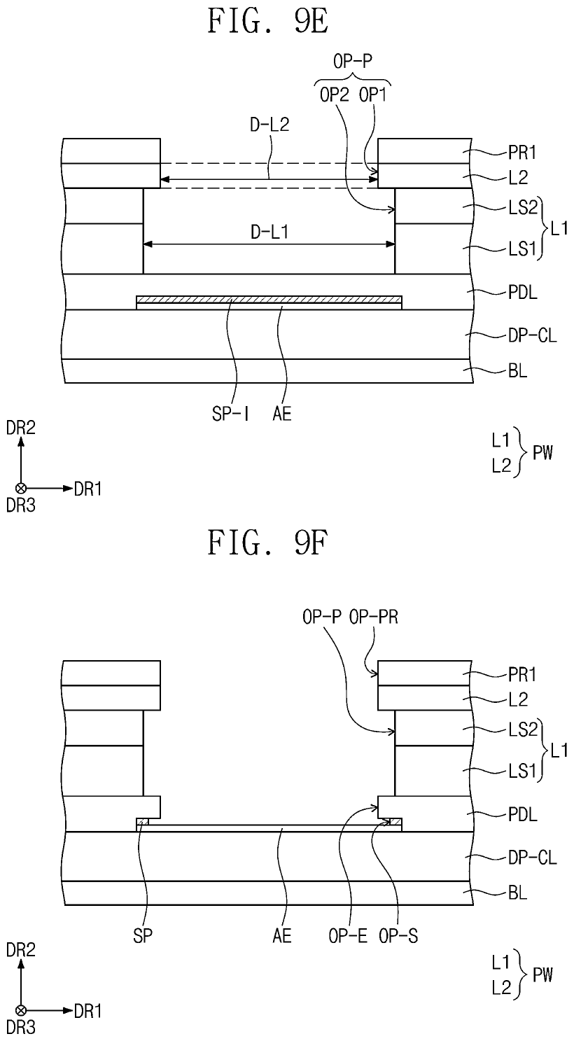

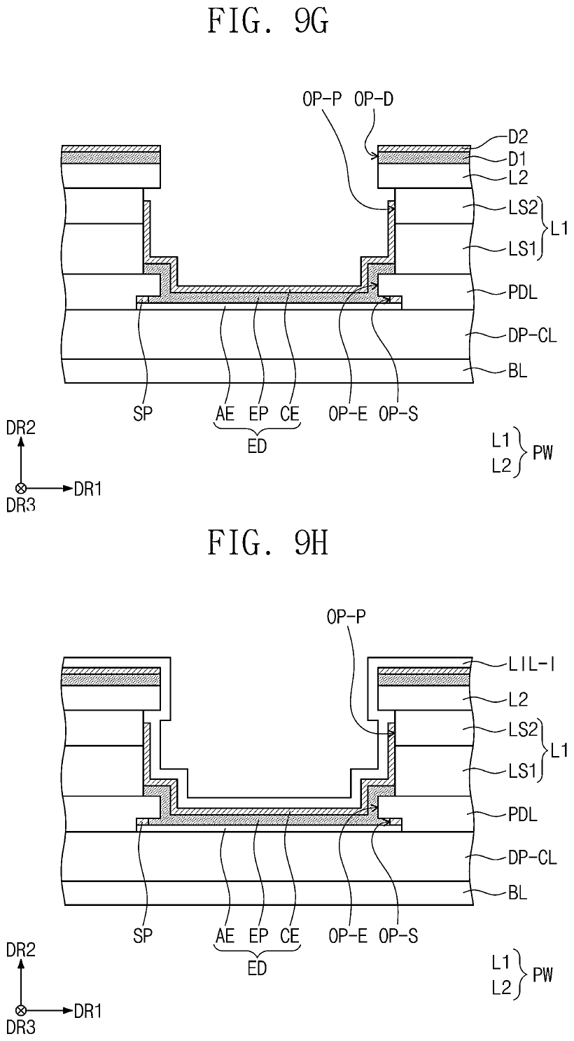

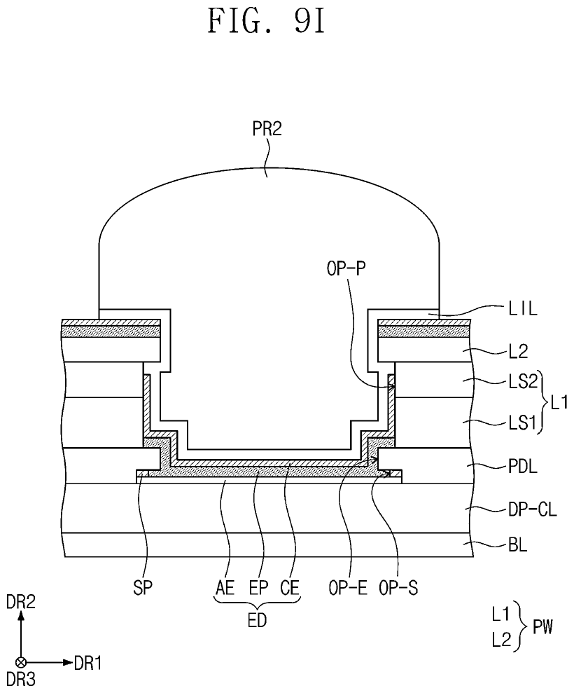

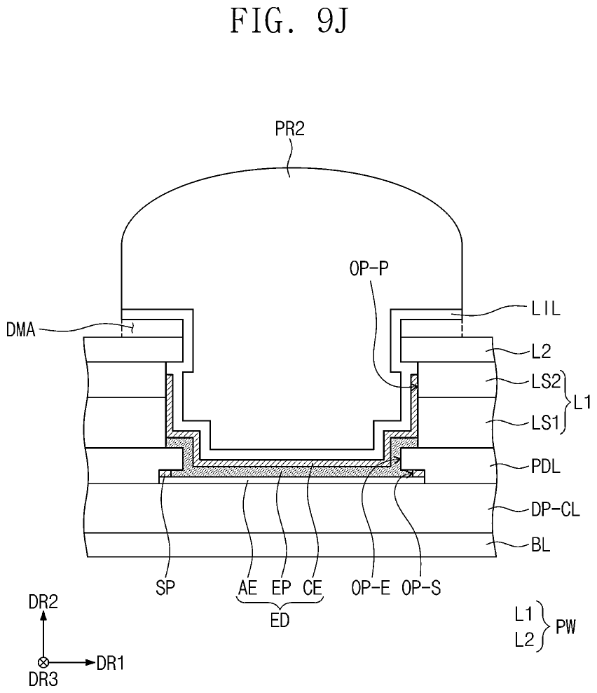

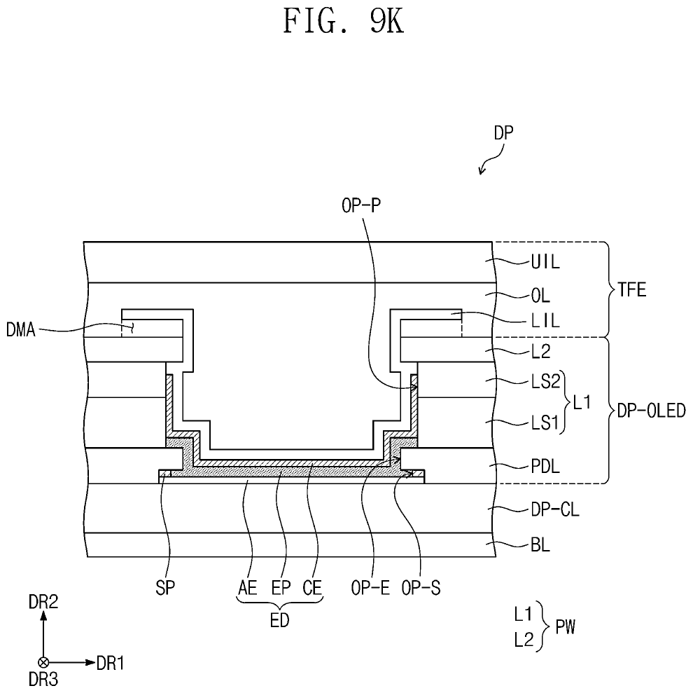

A dummy region DMA may be formed on the barrier wall PW. In detail, on the section, the dummy region DMA may be formed between the barrier wall PW and a lower inorganic encapsulation pattern LIL. The dummy region DMA may be defined as a region where first to third dummy layers D1 and D2 (refer to FIG. 9G) are formed and removed during a display panel manufacturing process that will be described below.

The thin film encapsulation layer TFE may be disposed on the display element layer DP-OLED. The thin film encapsulation layer TFE may include the lower inorganic encapsulation pattern LIL, an organic encapsulation film OL, and an upper inorganic encapsulation film UIL.

The lower inorganic encapsulation pattern LIL may be formed to correspond to the light emitting opening OP-E. The lower inorganic encapsulation pattern LIL may be disposed on the cathode CE and may cover the light emitting element ED. In detail, one portion of the lower inorganic encapsulation pattern LIL may be formed in the barrier wall opening OP-P, and the other portion of the lower inorganic encapsulation pattern LIL may be formed on the barrier wall PW.

The organic encapsulation film OL may be disposed on the lower inorganic encapsulation pattern LIL to cover the lower inorganic encapsulation pattern LIL and may provide a flat upper surface. A portion of the organic encapsulation film OL may fill the dummy region DMA. The upper inorganic encapsulation film UIL may be disposed on the organic encapsulation film OL.

The lower inorganic encapsulation pattern LIL and the upper inorganic encapsulation film UIL may protect the display element layer DP-OLED from moisture/oxygen, and the organic encapsulation film OL may protect the display element layer DP-OLED from foreign matter such as dust particles.

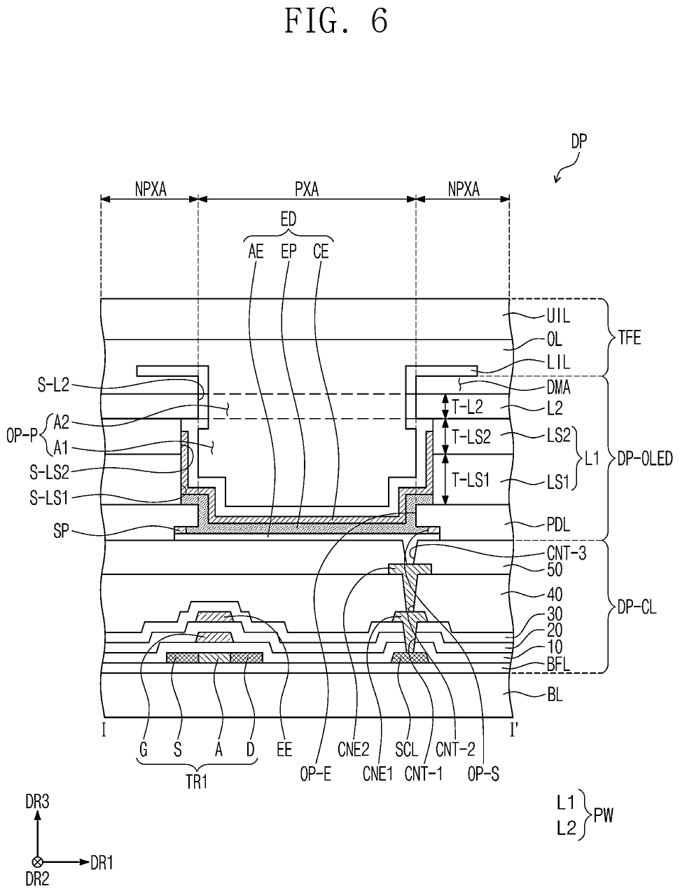

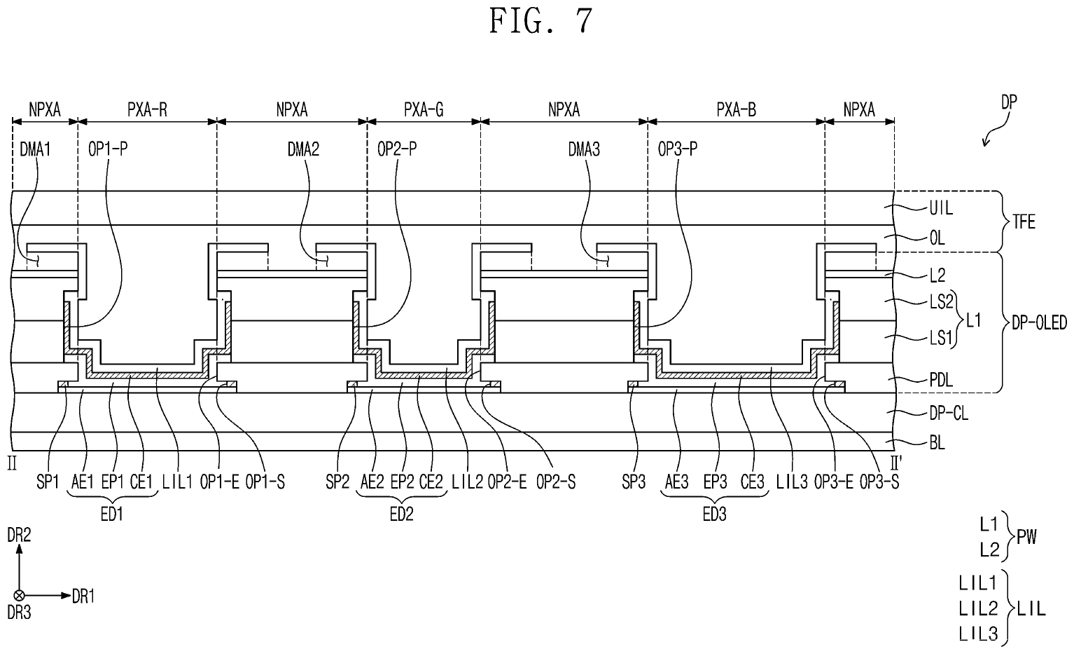

FIG. 7 is a sectional view taken along line II-II′ of FIG. 5. FIG. 7 is an enlarged view illustrating one first emissive region PXA-R, one second emissive region PXA-G, and one third emissive region PXA-B, and the description of the emissive region PXA of FIG. 6 may be identically applied to each of the first to third emissive regions PXA-R, PXA-G, and PXA-B of FIG. 7.

Referring to FIG. 7, the display panel DP may include the base layer BL, the circuit element layer DP-CL, the display element layer DP-OLED, and the thin film encapsulation layer TFE. The display element layer DP-OLED may include light emitting elements ED1, ED2, and ED3, sacrificial patterns SP1, SP2, and SP3, the pixel defining layer PDL, and the barrier wall PW.

The light emitting elements ED1, ED2, and ED3 may include the first light emitting element ED1, the second light emitting element ED2, and the third light emitting element ED3. The first light emitting element ED1 may include a first anode AE1, a first emission pattern EP1, and a first cathode CE1. The second light emitting element ED2 may include a second anode AE2, a second emission pattern EP2, and a second cathode CE2. The third light emitting element ED3 may include a third anode AE3, a third emission pattern EP3, and a third cathode CE3. The first to third anodes AE1, AE2, and AE3 may be provided in patterns. In an embodiment, the first emission pattern EP1 may provide red light, the second emission pattern EP2 may provide green light, and the third emission pattern EP3 may provide blue light.

First to third light emitting openings OP1-E, OP2-E, and OP3-E may be defined in the pixel defining layer PDL. The first light emitting opening OP1-E may expose at least a portion of the first anode AE1. The second light emitting opening OP2-E may expose at least a portion of the second anode AE2. The third light emitting opening OP3-E may expose at least a portion of the third anode AE3.

In this embodiment, the first emissive region PXA-R may be defined as a region of the upper surface of the first anode AE1 exposed by the first light emitting opening OP1-E. The second emissive region PXA-G may be defined as a region of the upper surface of the second anode AE2 exposed by the second light emitting opening OP2-E. The third emissive region PXA-B may be defined as a region of the upper surface of the third anode AE3 exposed by the third light emitting opening OP3-E.

The sacrificial patterns SP1, SP2, and SP3 may include the first sacrificial pattern SP1, the second sacrificial pattern SP2, and the third sacrificial pattern SP3. The first to third sacrificial patterns SP1, SP2, and SP3 may be disposed on the upper surfaces of the first to third anodes AE1, AE2, and AE3, respectively. First to third sacrificial openings OP1-S, OP2-S, and OP3-S overlapping the first to third light emitting openings OP1-E, OP2-E, and OP3-E may be defined in the first to third sacrificial patterns SP1, SP2, and SP3, respectively.

In this embodiment, first to third barrier wall openings OP1-P, OP2-P, and OP3-P overlapping the first to third light emitting openings OP1-E, OP2-E, and OP3-E, respectively, may be defined in the barrier wall PW. Each of the first to third barrier wall openings OP1-P, OP2-P, and OP3-P may include the first region A1 (refer to FIG. 6) and the second region A2 (refer to FIG. 6) described above with reference to FIG. 6. The first barrier wall layer L1 may include the first inner surfaces S-LS1 and S-LS2 (refer to FIG. 6) that define the first regions A1 of the first to third barrier wall openings OP1-P, OP2-P, and OP3-P, and the second barrier wall layer L2 may include the second inner surfaces S-L2 (refer to FIG. 6) that define the second regions A2 of the first to third barrier wall openings OP1-P, OP2-P, and OP3-P.

The first emission pattern EP1 and the first cathode CE1 may be disposed in the first barrier wall opening OP1-P, the second emission pattern EP2 and the second cathode CE2 may be disposed in the second barrier wall opening OP2-P, and the third emission pattern EP3 and the third cathode CE3 may be disposed in the third barrier wall opening OP3-P.

In this embodiment, the first to third emission patterns EP1, EP2, and EP3 and the first to third cathodes CE1, CE2, and CE3 may be physically separated by the second barrier wall layer L2 that forms tip portions and may be formed in the light emitting openings OP1-E, OP2-E, and OP3-E and the barrier wall openings OP1-P, OP2-P, and OP3-P.

According to the disclosure, first emission patterns EP1 may be subjected to patterning and deposited in pixel units by the tip portions defined in the barrier wall PW. For example, the first emission patterns EP1 may be commonly formed using an open mask, but may be readily divided from one another in pixel units by the barrier wall PW.

In contrast, in case that the first emission patterns EP1 are subjected to patterning using a fine metal mask (FMM), a spacer for support that protrudes from the conductive barrier wall has to be provided to support the fine metal mask. Furthermore, the fine metal mask may be spaced, by the height of the barrier wall and the spacer, apart from a base surface on which the patterning is performed, and therefore there may be a limitation in the implementation of high resolution. Since the fine metal mask is brought into contact with the spacer, foreign matter may remain on the spacer after the patterning process of the first emission patterns EP1, or the spacer may be damaged by a dent defect in the fine metal mask. Accordingly, a defective display panel may be formed.

According to this embodiment, since the barrier wall PW is included, the physical separation between the light emitting elements ED1, ED2, and ED3 may be readily achieved. Accordingly, current leakage or a driving error between the adjacent emissive regions PXA-R, PXA-G, and PXA-B may be prevented, and the light emitting elements ED1, ED2, and ED3 may be independently driven.

By way of example, by making the first emission patterns EP1 subject to patterning without a mask in contact with an internal component in the display region DA (refer to FIG. 1B), a defect rate may be reduced, and thus the display panel DP with improved process reliability may be provided. Since the patterning is possible even without the separate spacer for support that protrudes from the barrier wall PW, the areas of the emissive regions PXA-R, PXA-G, and PXA-B may be scaled down, and thus the display panel DP capable of readily implementing high resolution may be provided.

Furthermore, in the manufacture of the large-area display panel DP, the manufacture of a large-area mask may be omitted. Accordingly, process costs may be reduced, and the display panel DP may not be affected by defects that are likely to occur in the large-area mask. Thus, the display panel DP with improved process reliability may be provided. The description of the first emission patterns EP1 may be identically applied to second emission patterns EP2 and third emission patterns EP3.

The thin film encapsulation layer TFE may include lower inorganic encapsulation patterns LIL1, LIL2, and LIL3, the organic encapsulation film OL, and the upper inorganic encapsulation film UIL.

In this embodiments, the lower inorganic encapsulation patterns LIL1, LIL2, and LIL3 may include the first lower inorganic encapsulation pattern LIL1, the second lower inorganic encapsulation pattern LIL2, and the third lower inorganic encapsulation pattern LIL3. The first to third lower inorganic encapsulation patterns LIL1, LIL2, and LIL3 may overlap the first to third light emitting openings OP1-E, OP2-E, and OP3-E, respectively. The first to third lower inorganic encapsulation patterns LIL1, LIL2, and LIL3 may be provided in the form of patterns spaced apart from each other.

The first lower inorganic encapsulation pattern LIL1 may cover the first light emitting element ED1. One portion of the first lower inorganic encapsulation pattern LIL1 may be formed in the first barrier wall opening OP1-P, and the other portion of the first lower inorganic encapsulation pattern LIL1 may be formed on the barrier wall PW. On the section, a first dummy region DMA1 may be formed between the barrier wall PW defining the first barrier wall opening OP1-P and the first lower inorganic encapsulation pattern LIL1.

The second lower inorganic encapsulation pattern LIL2 may cover the second light emitting element ED2. One portion of the second lower inorganic encapsulation pattern LIL2 may be formed in the second barrier wall opening OP2-P, and the other portion of the second lower inorganic encapsulation pattern LIL2 may be formed on the barrier wall PW. On the section, a second dummy region DMA2 may be formed between the barrier wall PW defining the second barrier wall opening OP2-P and the second lower inorganic encapsulation pattern LIL2.

The third lower inorganic encapsulation pattern LIL3 may cover the third light emitting element ED3. One portion of the third lower inorganic encapsulation pattern LIL3 may be formed in the third barrier wall opening OP3-P, and the other portion of the third lower inorganic encapsulation pattern LIL3 may be formed on the barrier wall PW. On the section, a third dummy region DMA3 may be formed between the barrier wall PW defining the third barrier wall opening OP3-P and the third lower inorganic encapsulation pattern LIL3.

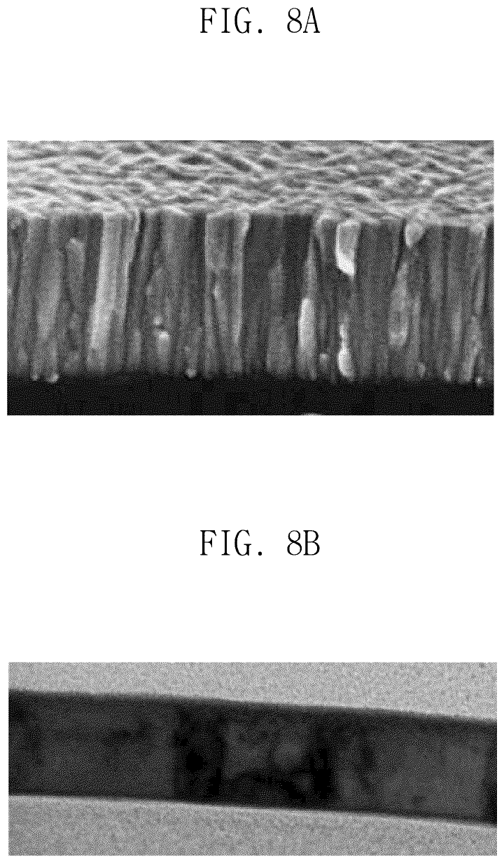

FIG. 8A is a photo of a section of a second sub-layer according to a comparative example. FIG. 8B is a photo of a section of the second sub-layer LS2 (refer to FIG. 6) according to an embodiment.

Referring to FIG. 8A, a portion of a barrier wall including a conductive material in the related art (for example, a portion corresponding to the second sub-layer LS2) may have a columnar crystal structure. Therefore, the barrier wall may be vulnerable to moisture introduced from the side of the barrier wall.

Referring to FIGS. 6 and 8B, the second sub-layer LS2 of the first barrier wall layer L1 of the disclosure may include at least one of an amorphous molybdenum alloy and an amorphous tungsten alloy. The second sub-layer LS2 may not have a columnar crystal structure. The adhesive force between the second sub-layer LS2 and the cathode CE may be improved, and moisture penetration reliability may be improved. Accordingly, pixel defects (dark spots, pixel shrinkage, and the like) of the display panel DP (refer to FIG. 6) caused by foreign matter be reduced or eliminated.

The first barrier wall layer L1 may include the first sub-layer LS1 and the second sub-layer LS2 including molybdenum or tungsten. Since the first barrier wall layer L1 may include molybdenum or tungsten, a phenomenon in which an oxide film is formed on the first barrier wall layer L1 so that electrical resistance is increased may be reduced or eliminated. For example, an interfacial oxide layer may not be formed on the barrier wall PW of the disclosure so that electrical resistance may be low, and the electrical reliability of the display panel DP may be improved.

FIGS. 9A to 9K are sectional views illustrating steps of a display panel manufacturing method according to an embodiment. In describing FIGS. 9A to 9K, components identical/similar to the components described above with reference to FIGS. 1 to 7 will be assigned with identical/similar reference numerals, and repetitive descriptions will be omitted.

The display panel manufacturing method according to the disclosure may include a step of providing a preliminary display panel including a base layer and a pixel defining layer disposed on the base layer, a step of forming a first preliminary barrier wall layer including an amorphous alloy on the preliminary display panel, a step of forming a second preliminary barrier wall layer on the first preliminary barrier wall layer, a step of forming a second barrier wall layer having a first opening defined therein by etching the second preliminary barrier wall layer, and a step of forming a first barrier wall layer having a second opening defined therein by etching the first preliminary barrier wall layer.

Hereinafter, a method of forming one light emitting element (for example, the first light emitting element ED1 (refer to FIG. 7)) and a lower inorganic encapsulation pattern (for example, the first lower inorganic encapsulation pattern LIL1 (refer to FIG. 7)), an organic encapsulation film OL, and an upper inorganic encapsulation film UIL that cover the light emitting element (for example, the first light emitting element ED1) will be described with reference to FIGS. 9A to 9K. A display panel formed through the method illustrated in FIGS. 9A and 9K may correspond to the display panel DP of FIG. 6.

Referring to FIG. 9A, the display panel manufacturing method may include the step of providing the preliminary display panel DP-I. The preliminary display panel DP-I provided in this embodiment may include the base layer BL, a circuit element layer DP-CL, an anode AE, a preliminary sacrificial pattern SP-I, and the pixel defining layer PDL.

The circuit element layer DP-CL may be formed through a conventional circuit element manufacturing process of forming an insulating layer, a semiconductor layer, and a conductive layer by coating, deposition, or the like and forming a semiconductor pattern, a conductive pattern, and a signal line by selectively making the insulating layer, the semiconductor layer, and the conductive layer subject to patterning by photolithography and etching processes.

The anode AE and the preliminary sacrificial pattern SP-I may be formed by the same patterning process. The pixel defining layer PDL may be disposed on the base layer BL. The pixel defining layer PDL may cover both the anode AE and the preliminary sacrificial pattern SP-I.

Referring to FIG. 9B, the display panel manufacturing method may include the step of forming the first preliminary barrier wall layer L1-I including the amorphous alloy on the preliminary display panel DP-I (refer to FIG. 9A) and the step of forming the second preliminary barrier wall layer L2-I on the first preliminary barrier wall layer L1-I.

The step of forming the first preliminary barrier wall layer L1-I including the amorphous alloy on the preliminary display panel DP-I (refer to FIG. 9A) may include a step of forming a first preliminary sub-layer LS1-I on the pixel defining layer PDL and a step of forming a second preliminary sub-layer LS2-I on the first preliminary sub-layer LS1-I. The first preliminary barrier wall layer L1-I and the second preliminary barrier wall layer L2-I may form a preliminary barrier wall PW-I.

The step of forming the first preliminary sub-layer LS1-I may include a step of depositing a conductive material to a thickness in a range of about 2000 Å to about 5000 Å. For example, the step of forming the first preliminary sub-layer LS1-I may be performed by a process of depositing the conductive material. For example, the conductive material may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide. In this embodiment, the first preliminary sub-layer LS1-I may include aluminum (Al).

The step of forming the second preliminary sub-layer LS2-I may include a step of depositing the amorphous alloy to a thickness in a range of about 2000 Å to about 3000 Å. For example, the second preliminary sub-layer LS2-I may include at least one of an amorphous molybdenum alloy and an amorphous tungsten alloy.

The step of forming the second preliminary barrier wall layer L2-I may include a step of depositing a conductive material to a thickness in a range of about 1000 Å to about 2500 Å. For example, the step of forming the second preliminary barrier wall layer L2-I may be performed by a process of depositing the conductive material. For example, the conductive material may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide. In this embodiment, the second preliminary barrier wall layer L2-I may include titanium (Ti).

Referring to FIG. 9C, the display panel manufacturing method may include a step of forming a first photoresist layer PR1 on the preliminary barrier wall PW-I. The first photoresist layer PR1 may be formed by forming a preliminary photoresist layer on the preliminary barrier wall PW-I and thereafter making the preliminary photoresist layer subject to patterning using a photo mask. Through the patterning process, a photo opening OP-PR overlapping the anode AE may be formed in the first photoresist layer PR1.

Referring to FIGS. 9D and 9E, the display panel manufacturing method may include the step of forming the second barrier wall layer L2 by etching the second preliminary barrier wall layer L2-I such that a barrier wall PW is formed from the preliminary barrier wall PW-I (refer to FIG. 9C) and the step of forming the first barrier wall layer L1 by etching the first preliminary barrier wall layer L1-I.

As illustrated in FIG. 9D, the step of etching the second preliminary barrier wall layer L2-I may be performed by dry etching the second preliminary barrier wall layer L2-I using the first photoresist layer PR1 as a mask. By removing an etched portion of the second preliminary barrier wall layer L2-I, the first opening OP1 may be formed in the second preliminary barrier wall layer L2-I, and the second barrier wall layer L2 having the first opening OP1 defined therein may be formed from the second preliminary barrier wall layer L2-I.

As illustrated in FIG. 9E, the step of etching the first preliminary barrier wall layer L1-I may be performed by wet etching the first preliminary barrier wall layer L1-I using the first photoresist layer PR1 as a mask. By removing an etched portion of the first preliminary barrier wall layer L1-I, the second opening OP2 may be formed in the first preliminary barrier wall layer L1-I, and the first barrier wall layer L1 having the second opening OP2 defined therein may be formed from the first preliminary barrier wall layer L1-I. The first opening OP1 and the second opening OP2 may form a barrier wall opening OP-P. The first opening OP1 and the second opening OP2 of the barrier wall opening OP-P may be openings integral with each other.

The barrier wall opening OP-P may include the first region A1 (refer to FIG. 6) and the second region A2 (refer to FIG. 6) that are sequentially disposed in the thickness direction (for example, the third direction DR3). The first region A1 may correspond to the second opening OP2, and the second region A2 may correspond to the first opening OP1. The width D-L2 of the first opening OP1 in the first direction DR1 may be smaller than the width D-L1 of the second opening OP2 in the first direction DR1.

In detail, the step of forming the first barrier wall layer L1 by etching the first preliminary barrier wall layer L1-I may include a step of forming a second sub-layer LS2 by etching the second preliminary sub-layer LS2-I and a step of forming a first sub-layer LS1 by etching the first preliminary sub-layer LS1-I.

The second preliminary sub-layer LS2-I may be wet etched by using the first photoresist layer PR1 as a mask. By removing an etched portion of the second preliminary sub-layer LS2-I, the inner surface S-LS2 (refer to FIG. 6) that defines the second opening OP2 may be formed in the second preliminary sub-layer LS2-I, and the second sub-layer LS2 may be formed from the second preliminary sub-layer LS2-I. The first preliminary sub-layer LS1-I may be wet etched by using the first photoresist layer PR1 as a mask. By removing an etched portion of the first preliminary sub-layer LS1-I, the inner surface S-LS1 (refer to FIG. 6) that defines the second opening OP2 may be formed in the first preliminary sub-layer LS1-I, and the first sub-layer LS1 may be formed from the first preliminary sub-layer LS1-I. The inner surface S-LS1 of the first sub-layer LS1 may be aligned with the inner surface S-LS2 of the second sub-layer LS2.

The first barrier wall layer L1 may include the first inner surface S-LS1 and S-LS2 that defines the first region A1 of the barrier wall opening OP-P, and the second barrier wall layer L2 may include the second inner surface S-L2 (refer to FIG. 6) that defines the second region A2 of the barrier wall opening OP-P.

The wet etching process in this embodiment may be performed in an environment in which the etch selectivity between the first barrier wall layer L1 and the second barrier wall layer L2 is large. Accordingly, the inner surface of the barrier wall PW that defines the barrier wall opening OP-P may have an undercut shape on the section. By way of example, since the etch rate of the first barrier wall layer L1 by an etchant is higher than the etch rate of the second barrier wall layer L2 by the etchant, the first barrier wall layer L1 may be mainly etched. Accordingly, the first inner surface S-LS1 and S-LS2 of the first barrier wall layer L1 may be recessed inward in case that compared to the second inner surface S-L2 of the second barrier wall layer L2. A tip portion may be formed in the barrier wall PW by a portion of the second barrier wall layer L2 that protrudes from the first barrier wall layer L1.

According to the disclosure, since the undercut shape is formed by dry etching the second barrier wall layer L2 and wet etching the first barrier wall layer L1 in batches, the process of forming the barrier wall PW may be facilitated. Accordingly, the process reliability and efficiency of the display panel DP may be improved.

Although FIGS. 9D and 9E illustrate an example that the one barrier wall opening OP-P is formed, the disclosure is not limited thereto. In an embodiment, the step of forming the barrier wall opening OP-P may include a step of simultaneously forming the barrier wall openings OP1-P, OP2-P, and OP3-P (refer to FIG. 7) that correspond to the first to third emissive regions PXA-R, PXA-G, and PXA-B (refer to FIG. 7). In an embodiment, the step of forming the barrier wall opening OP-P may include a step of forming only the first barrier wall opening OP1-P corresponding to the first emissive region PXA-R. For example, after the first barrier wall opening OP1-P corresponding to the first light emissive region PXA-R is formed and the first light emitting element ED1 (refer to FIG. 7) is formed through a subsequent process, the second barrier wall opening OP2-P corresponding to the second emissive region PXA-G may be formed. Through a subsequent process, the second light emitting element ED2 (refer to FIG. 7) may be formed, and the third barrier wall opening OP3-P corresponding to the third emissive region PXA-B may be formed.

Referring to FIG. 9F, the display panel manufacturing method may include a step of etching the pixel defining layer PDL and a step of etching the preliminary sacrificial pattern SP-I (refer to FIG. 9E). The etching process of the pixel defining layer PDL may be performed by a dry etching method, and the pixel defining layer PDL may be etched using the first photoresist layer PR1 and the barrier wall PW (for example, the second barrier wall layer L2) as a mask. A light emitting opening OP-E corresponding to the barrier wall opening OP-P may be formed in the pixel defining layer PDL.

The etching process of the preliminary sacrificial pattern SP-I may be performed by a wet etching method, and the preliminary sacrificial pattern SP-I may be etched using the first photoresist layer PR1 and the barrier wall PW (for example, the second barrier wall layer L2) as a mask. A sacrificial opening OP-S overlapping the light emitting opening OP-E may be formed in a sacrificial pattern SP formed by etching the preliminary sacrificial pattern SP-I. At least a portion of the anode AE may be exposed from the sacrificial pattern SP and the pixel defining layer PDL by the sacrificial opening OP-S and the light emitting opening OP-E.

The etching process of the sacrificial pattern SP may be performed in an environment in which the etch selectivity between the sacrificial pattern SP and the anode AE is high, and thus the anode AE may be prevented from being etched together. For example, since the sacrificial pattern SP having a higher etch rate than the anode AE is disposed between the pixel defining layer PDL and the anode AE, the anode AE may be prevented from being etched together and damaged during the etching process.

Referring to FIG. 9G, the display panel manufacturing method may include a step of forming a light emitting element ED in the barrier wall opening OP-P after removing the first photoresist layer PR1 (refer to FIG. 9F). The step of forming the light emitting element ED may include a step of forming an emission pattern EP and a step of forming a cathode CE.

The step of forming the emission pattern EP may include a deposition process of an emissive layer. In an embodiment, the deposition process of the emissive layer may be a thermal evaporation process. However, this is illustrative, and the deposition process of the emissive layer is not limited to the above example. The emissive layer may be divided by the tip portion formed in the barrier wall PW and may form the emission pattern EP and the first dummy layer D1. The emission pattern EP may be formed on the anode AE in the light emitting opening OP-E and the barrier wall opening OP-P. One portion of the first dummy layer D1 may be formed in the second and third barrier wall openings OP2-P and OP3-P (refer to FIG. 7) or the second and third light emitting openings OP2-E and OP3-E (refer to FIG. 7), and another portion of the first dummy layer D1 may be formed on the barrier wall PW.

For example, in the step of forming the emission pattern EP, the first dummy layer D1 spaced apart from the emission pattern EP may be formed together. The first dummy layer D1 may include an organic material. For example, the first dummy layer D1 may include the same material as the emission pattern EP. The first dummy layer D1 may be simultaneously formed with the emission pattern EP through one process and may be separated from the emission pattern EP by the undercut shape of the barrier wall PW.

The step of forming the cathode CE may include a deposition process of a cathode layer. In an embodiment, the deposition process of the cathode layer may be a sputtering process. However, this is illustrative, and the deposition process of the cathode layer is not limited to the above example. The cathode layer may be divided by the tip portion formed in the barrier wall PW and may form the cathode CE and the second dummy layer D2. The cathode CE may be formed on the emission pattern EP in the light emitting opening OP-E and the barrier wall opening OP-P. One portion of the second dummy layer D2 may be formed in the second and third barrier wall openings OP2-P and OP3-P or the second and third light emitting openings OP2-E and OP3-E, and another portion of the second dummy layer D2 may be formed on the barrier wall PW.

For example, in the step of forming the cathode CE, the second dummy layer D2 spaced apart from the cathode CE may be formed together. The second dummy layer D2 may include a conductive material. For example, the second dummy layer D2 may include the same material as the cathode CE. The second dummy layer D2 may be simultaneously formed with the cathode CE through one process and may be separated from the cathode CE by the undercut shape of the barrier wall PW.

The anode AE, the emission pattern EP, and the cathode CE may be sequentially stacked in the third direction DR3. The anode AE, the emission pattern EP, and the cathode CE may form the light emitting element ED. The first dummy layer D1 and the second dummy layer D2 may be sequentially stacked in the third direction DR3. A dummy opening OP-D may be formed in the first dummy layer D1 and the second dummy layer D2.

In an embodiment, the display panel manufacturing method may further include a step of forming a capping pattern. The step of forming the capping pattern may include a deposition process of a capping pattern layer. The deposition process of the capping pattern layer may be a thermal evaporation process. The capping pattern layer may be divided by the tip portion formed in the barrier wall PW and may form the capping pattern and the third dummy layer. The capping pattern may be formed on the cathode CE in the barrier opening OP-P. One portion of the third dummy layer may be formed in the second and third barrier wall openings OP2-P and OP3-P, and another portion of the third dummy layer may be formed on the barrier wall PW.

For example, in the step of forming the capping pattern, the third dummy layer spaced apart from the capping pattern may be formed together. The third dummy layer may include a conductive material. For example, the third dummy layer may include the same material as the capping pattern. The third dummy layer may be simultaneously formed with the capping pattern through one process and may be separated from the capping pattern by the undercut shape of the barrier wall PW.

Referring to FIGS. 9H and 9I, the display panel manufacturing method may include a step of forming the lower inorganic encapsulation pattern LIL that covers the light emitting element ED. The step of forming the lower inorganic encapsulation pattern LIL may include a step of depositing a lower inorganic encapsulation layer LIL-I and a step of removing a portion of the lower inorganic encapsulation layer LIL-I that does not overlap the light emitting element ED.

Referring to FIG. 9H, the step of forming the lower inorganic encapsulation pattern LIL may include the step of depositing the lower inorganic encapsulation layer LIL-I. The lower inorganic encapsulation layer LIL-I may be formed through a deposition process. In an embodiment, the lower inorganic encapsulation layer LIL-I may be formed through a chemical vapor deposition (CVD) process. The lower inorganic encapsulation layer LIL-I may be formed to cover the barrier wall opening OP-P and the barrier wall PW.

Referring to FIG. 9I, the step of forming the lower inorganic encapsulation pattern LIL may include a step of forming a second photoresist layer PR2 and the step of removing the portion of the lower inorganic encapsulation layer LIL-I that does not overlap the light emitting element ED.

In the step of forming the second photoresist layer PR2, the second photoresist layer PR2 may be formed by forming a preliminary photoresist layer and making the preliminary photoresist layer subject to patterning using a photo mask. Through the patterning process, the second photoresist layer PR2 may be formed in the form of a pattern corresponding to the light emitting element ED.

In the step of removing the portion of the lower inorganic encapsulation layer LIL-I that does not overlap the light emitting element ED, the lower inorganic encapsulation layer LIL-I may be subjected to patterning such that the portion of the lower inorganic encapsulation layer LIL-I that does not overlap the light emitting element ED (for example, the second and third light emitting elements ED2 and ED3 (refer to FIG. 7)) is removed by dry etching the lower inorganic encapsulation layer LIL-I using the second photoresist layer PR2 as a mask. The lower inorganic encapsulation pattern LIL overlapping the light emitting element ED may be formed from the patterned lower inorganic encapsulation layer LIL-I.

Referring to FIG. 9J, the display panel manufacturing method may include a step of forming a dummy region DMA by removing the dummy layers D1 and D2 (refer to FIG. 9I). The second dummy layer D2 may be removed by wet etching, and the first dummy layer D1 may be removed by a stripper.

The dummy region DMA may be formed between the barrier wall PW and the lower inorganic encapsulation pattern LIL by the removal of the dummy layers D1 and D2. The height of the dummy region DMA may correspond to the thickness of the dummy layers D1 and D2, and the thickness of the dummy layers D1 and D2 may correspond to the thickness of the emission pattern EP and the cathode CE.

Referring to FIG. 9K, the display panel manufacturing method may include a step of completing the display panel DP by forming the organic encapsulation film OL and the upper inorganic encapsulation film UIL after removing the second photoresist layer PR2 (refer to FIG. 9J). The organic encapsulation film OL may be formed by applying an organic material using an inkjet method, but is not limited thereto. The organic encapsulation film OL provides a flat upper surface. The upper inorganic encapsulation film UIL may be formed by depositing an inorganic material. Accordingly, the display panel DP including the base layer BL, the circuit element layer DP-CL, the display element layer DP-OLED, and the thin film encapsulation layer TFE may be formed.

A step of forming barrier wall openings and light emitting openings corresponding to emissive regions having other colors in the barrier wall PW and the pixel defining layer PDL, a step of forming light emitting elements that provide the other colors, and a step of forming lower inorganic encapsulation patterns covering the light emitting elements that provide the other colors may be additionally performed between the step of forming the lower inorganic encapsulation pattern LIL and the step of completing the display panel DP. Accordingly, the display panel DP including the first to third light emitting elements ED1, ED2, and ED3, the first to third dummy regions DMA1, DMA2, and DMA3, and the first to third lower inorganic encapsulation patterns LIL1, LIL2, and LIL3 illustrated in FIG. 7 may be formed.

As described above, the second sub-layer of the first barrier wall layer may include at least one of an amorphous molybdenum alloy or an amorphous tungsten alloy. The second sub-layer may not have a columnar crystal structure. The adhesive force between the second sub-layer and the cathode may be improved, and moisture penetration reliability may be improved. Accordingly, pixel defects (dark spots, pixel shrinkage, and the like) of the display panel caused by foreign matter be reduced or eliminated.

The first barrier wall layer may include the first sub-layer and the second sub-layer including molybdenum or tungsten. Since the first barrier wall layer may include molybdenum or tungsten, a phenomenon in which an oxide film is formed on the first barrier wall layer so that electrical resistance is increased may be reduced or eliminated. For example, an interfacial oxide layer may not be formed on the barrier wall so that electrical resistance may be low, and the electrical reliability of the display panel may be improved.

While the disclosure has been described with reference to embodiments thereof, it will be apparent to those of ordinary skill in the art that various changes and modifications may be made thereto without departing from the spirit and scope of the disclosure and as set forth in the following claims.

What is claimed is:

1. A display panel comprising:
a base layer;
a pixel defining layer disposed on the base layer, the pixel defining layer having a light emitting opening defined in the pixel defining layer;
a barrier wall having a barrier wall opening defined in the barrier wall that overlaps the light emitting opening, the barrier wall including a first barrier wall layer disposed on the pixel defining layer and a second barrier wall layer disposed on the first barrier wall layer; and
a light emitting element disposed in the barrier wall opening, the light emitting element including an anode, an intermediate layer, and a cathode that contacts the barrier wall,
wherein the first barrier wall layer includes an amorphous alloy.

2. The display panel of claim 1, wherein
the first barrier wall layer defines a first region of the barrier wall opening,
the second barrier wall layer defines a second region of the barrier wall opening, and
the first region of the barrier wall opening has a greater width in a first direction than the second region of the barrier wall opening.

3. The display panel of claim 1, wherein
the first barrier wall layer includes a first sub-layer disposed on the pixel defining layer and a second sub-layer disposed on the first sub-layer, and
the second sub-layer includes the amorphous alloy.

4. The display panel of claim 3, wherein an inner surface of the first sub-layer is aligned with an inner surface of the second sub-layer.

5. The display panel of claim 4, wherein
the cathode extends along the inner surface of the first sub-layer and the inner surface of the second sub-layer, and
an end of the cathode contacts the second sub-layer.

6. The display panel of claim 3, wherein the first sub-layer has a thickness in a range of about 2000 Å to about 5000 Å.

7. The display panel of claim 3, wherein the second sub-layer has a thickness in a range of about 2000 Å to about 3000 Å.

8. The display panel of claim 1, wherein the second barrier wall layer has a thickness in a range of about 1000 Å to about 2500 Å.

9. The display panel of claim 1, wherein the amorphous alloy includes at least one of an amorphous molybdenum alloy and an amorphous tungsten alloy.

10. The display panel of claim 1, further comprising:
a lower inorganic encapsulation pattern that covers the light emitting element,
wherein a dummy region is defined between the barrier wall and the lower inorganic encapsulation pattern.

11. The display panel of claim 10, further comprising:
an organic encapsulation film disposed on the lower inorganic encapsulation pattern,
wherein a portion of the organic encapsulation film fills the dummy region.

12. A method for manufacturing a display panel, the method comprising:
providing a preliminary display panel including a base layer and a pixel defining layer disposed on the base layer;
forming a first preliminary barrier wall layer including an amorphous alloy on the preliminary display panel;
forming a second preliminary barrier wall layer on the first preliminary barrier wall layer;
forming a second barrier wall layer having a first opening defined in the second barrier wall layer, by etching the second preliminary barrier wall layer; and
forming a first barrier wall layer having a second opening defined in the first barrier wall layer, by etching the first preliminary barrier wall layer,
wherein the first opening in the second barrier wall layer has a smaller width in a first direction than the second opening in the first barrier wall layer.

13. The method of claim 12, wherein the forming of the first preliminary barrier wall layer includes:
forming a first preliminary sub-layer on the pixel defining layer; and
forming a second preliminary sub-layer on the first preliminary sub-layer.

14. The method of claim 13, wherein the forming of the first preliminary sub-layer includes:
depositing a conductive material to a thickness in a range of about 2000 Å to about 5000 Å.

15. The method of claim 13, wherein the forming of the second preliminary sub-layer includes:
depositing the amorphous alloy to a thickness in a range of about 2000 Å to about 3000 Å.

16. The method of claim 13, wherein the second preliminary sub-layer includes at least one of an amorphous molybdenum alloy and an amorphous tungsten alloy.

17. The method of claim 13, wherein the forming of the first barrier wall layer having the second opening defined in the first barrier wall layer by etching the first preliminary barrier wall layer includes:
forming a second sub-layer by etching the second preliminary sub-layer; and
forming a first sub-layer by etching the first preliminary sub-layer.

18. The method of claim 17, wherein an inner surface of the first sub-layer is aligned with an inner surface of the second sub-layer.

19. The method of claim 12, wherein the forming of the second preliminary barrier wall layer includes:
depositing a conductive material to a thickness in a range of about 1000 Å to about 2500 Å.

20. The method of claim 12, further comprising:
forming a light emitting element in the second opening; and
forming a lower inorganic encapsulation pattern that covers the light emitting element.
